(19) United States
(12) Patent Application Publication
(10) Pub. No.: US 2022/0263526 A1
(43) Pub. Date: Aug. 18, 2022

(54) CIRCUIT ARRANGEMENT FOR TRANSMITTING RADIO SIGNALS AND METHOD FOR OPERATING A CIRCUIT ARRANGEMENT

(71) Applicant: Molex CVS Dabendorf GmbH, Zossen (DE)

(72) Inventors: Helmut KAUTGE, Stahnsdorf (DE); Lars LEHMANN, Wildau (DE); Ahmed SAYED, Berlin (DE)

(73) Assignee: Molex CVS Dabendorf GmbH, Zossen (DE)

(21) Appl. No.: 17/617,581

(22) PCT Filed: Jun. 16, 2020
(86) PCT No.: PCT/EP2020/066607

§ 371 Date: Dec. 8, 2021

(30) Foreign Application Priority Data
Jun. 19, 2019 (DE) 10 2019 208 987.9

(51) Int. Cl. H04B 1/00; H04B 1/3822; H03F 3/189

(52) U.S. Cl. CPC H04B 1/006; H04B 1/0057; H03F 3/189; H04B 1/3822

(57) ABSTRACT

The invention relates to a circuit arrangement and a method for operating a circuit arrangement for transmitting up-link and downlink signals between a terminal (2) and an antenna (3), wherein: the circuit arrangement (I) comprises at least one first uplink path (SP1, . . . , SP5, SPn) for transmitting a first uplink signal and a first downlink path (EP1) for transmitting a first downlink signal; the circuit arrangement (I) comprises means for providing the uplink signals and the downlink signals and means for detecting at least one uplink signal; the circuit arrangement (I) comprises means for establishing an activated state of the uplink path (SP1, . . . , SP5, SPn) to which the detected uplink signal is assigned; the circuit arrangement (I) comprises at least one further downlink path (EP2, . . . , EP5, EPn) for transmitting a further downlink signal and comprises means for establishing a simultaneously activated state of at least two downlink paths (EP1, . . . , EP5, EPn), wherein this activated state is established or maintained when at least one uplink signal is detected; and/or the circuit arrangement (I) comprises at least one further uplink path (SP1, . . . , SP5, SPn) for transmitting a further uplink signal and comprises means for establishing a simultaneously activated state of at least two uplink paths (SP1, . . . , SP5, SPn), wherein an activated state of at least two uplink paths (SP1, . . . , SP5, SPn) is established or maintained when an uplink signal or when at least two uplink signals is/are detected.

### TECHNICAL FIELD

The disclosure relates to a circuit arrangement for transmitting uplink and downlink signals which are transmitted between a terminal and an antenna, as well as a method for operating one such circuit arrangement.

### BACKGROUND

Known from the prior art are circuit arrangements for damping compensation, wherein DE 10 2007 004 911 A1 discloses e.g. a multi-band circuit arrangement for compensating the damping which occurs in signal paths between a transmitting and receiving device for radio communication and an external antenna used with this transmitting and receiving device.

DE 10 2009 027 358 A1 discloses a circuit of signal branches in a multiband circuit arrangement.

DE 10 2012 113 158 B4 discloses a circuit arrangement for compensating a damping occurring in an antenna line between a mobile radio terminal and an antenna, having several subbranches.

DE 10 2006 010 963 A1 also discloses a multiband circuit arrangement for compensating the damping of an antenna feeder cable to an external antenna for a mobile radio terminal.

WO 2018/144939 A1 discloses technologies for a signal amplifier.

The method according to the prior art disclose inter alia a so-called basic state, wherein in this basic state one or more downlink branches are activated, which facilitates the reception of incoming signals in all frequency bands and radio standards supported by the circuit arrangement. However, this basic state is set only in the absence of an uplink signal of a terminal operated with the circuit arrangement.

### SUMMARY

In the presence of an FDD uplink signal, particularly when the end device generates an uplink signal to be transmitted via the circuit arrangements, according to the prior art, the activation of precisely one transmission branch of the circuit arrangement takes place. Furthermore, the activation of precisely one downlink branch of the circuit arrangement takes place, specifically of a downlink branch corresponding to the transmission branch. In the presence of a TDD uplink signal according to the prior art, the activation of precisely one transmission branch of the circuit arrangement takes place. Furthermore, in the circuit arrangements or methods according to the prior art, only the support of one single terminal is disclosed.

It is desirable to increase a maximum possible data throughput rate of a circuit arrangement, in particular a data throughput rate for downlink signals and/or uplink signals.

Therefore, the technical problem arises of creating a circuit arrangement for transmitting uplink and downlink signals which are transmitted between one or more terminal(s) and at least one antenna, as well as a method for operating one such circuit arrangement, which increase a data throughput rate, in particular for the data transmitted by means of downlink signals and/or uplink signals. There is also the technical problem of facilitating a transmission of uplink and/or downlink signals from/to a plurality of terminals.

The solution to the technical problem results from the articles with the characteristics of the independent claims. Further advantageous embodiments of the disclosure result from the articles with the characteristics of the dependent claims.

Proposed is a circuit arrangement for transmitting uplink and downlink signals which are transmitted between precisely one or more terminal(s) and precisely one or more antenna(s). Thus, a compensation of losses in the transmission of these uplink and downlink signals, for example by means of losses originating in signal-conducting components, can occur.

A terminal can be a portable terminal, e.g. a terminal which can be carried by a user. A terminal of this sort can for example be a mobile telephone or a tablet. Furthermore, a terminal can, however, also be a modem or a control device, particularly of a vehicle, e.g. a telematics control unit. Thus, the terminal can also be a permanently installed terminal, e.g. a terminal which is permanently installed in the vehicle.

A plurality of uplink signals can be transmitted by the circuit arrangement. Preferably, uplink signals with frequencies from uplink frequency ranges which are different from one another can be able to be transmitted, wherein an uplink signal transmitted in an uplink frequency range has a frequency from this frequency range. Uplink frequency ranges which are different from one another can serve to transmit uplink signals according to a radio standard or various radio standards. Such standards can for example be a GSM standard, a UMTS standard, an LTE standard, a Wifi or 5G new radio standard.

An uplink frequency range can be assigned to precisely one, but also to a plurality of standards. Thus, it is possible for uplink signals according to different standards to be transmitted in the same uplink frequency range. In a case of this sort, the standard can be determined from a frequency of an uplink signal only by means of an additional signal analysis.

For example, signals according to GSM and/or LTE and/or UMTS and/or further standards can be transmitted in one uplink frequency range.

By means of the circuit arrangement, also a plurality of downlink signals can be transmitted. Preferably, downlink signals can be able to be transmitted having frequencies from downlink frequency ranges which are different from one another, wherein a downlink signal transmitted in a downlink frequency range has a frequency from this frequency range. Downlink frequency ranges which are different from one another can serve in particular for transmitting downlink signals according to the explained various standards. A downlink frequency range can in this regard be assigned to precisely one, but also to a plurality of standards. Thus, it is possible for downlink signals according to different standards to be transmitted in the same downlink frequency range. In a case of this sort, the standard can be determined from a frequency of a downlink signal only by means of an additional signal analysis.

Furthermore, uplink and downlink signals can in a time duplex method, which can also be described as TDD method (time division duplex method) or in a frequency duplex method, which can also be described as a FDD method (frequency division duplex method). The disclosure is not limited to the mentioned radio standards or duplex methods and thus relates to all radio standards and duplex methods already known to the person skilled in the art as well as all future radio standards and duplex experience.

It is also possible for one uplink frequency range and one downlink frequency range to be assigned to one standard, wherein these form a standard-specific frequency range pair. This frequency range pair can also be described as an FDD band. Such a frequency range part can for example, as described in more detail hereinafter, serve for signal transmission in an FDD method.

The circuit arrangement can comprise an interface on the terminal side. This can describe an interface by means of which a signal connection can be established between the circuit arrangement and the terminal. The interface on the terminal side can here facilitate a bidirectional transmission of signals. For example, the interface on the terminal side can comprise a so-called wireless coupler.

Furthermore, the circuit arrangement can comprise precisely one interface on the antenna side or a plurality of interfaces on the antenna side. This can relate to an interface via which a signal connection can be established between the circuit arrangement and one or more antenna(s). The antenna can be an antenna which is external to the terminal. However, it is also possible for the antenna(s) to be part of the circuit arrangement. In particular, the antenna can serve to receive signals which are transmitted by a base station. Furthermore, the antenna can serve to transmit signals which are to be transmitted to the base station or to a further device. The interface on the antenna side can here facilitate a bidirectional transmission of signals.

The circuit arrangement can in this regard be arranged in a vehicle, in particular a motor vehicle. The antenna which is external to the terminal can in this regard in particular be a vehicle antenna. The circuit arrangement can furthermore in particular be part of a mobile radio amplifier device or comprise or form a mobile radio amplifier device.

In the context of this disclosure, a connection can describe a signal connection. In particular, this can be a galvanic and/or inductive and/or capacitive connection. A connection is preferably a galvanic connection. Components of the circuit arrangement can preferably be connected by galvanic and inductive connections. The connection of the circuit arrangement to the terminal, however, can be an inductive connection or a capacitive connection.

An uplink path can here describe a signal path via which an uplink signal can be transmitted from the interface on the terminal side to the interface on the antenna side. In particular, the uplink signal can describe a signal which is generated by the terminal and transmitted to the interface on the terminal side.

A downlink path can here describe a signal path via which a downlink signal can be transmitted from the interface on the antenna side to the interface on the terminal side. In particular, the downlink signal can be a signal received by the antenna which is external to the terminal, which signal has been transmitted e.g. by the base station.

In an uplink path and/or downlink path can be arranged signal processing means. This can mean that the transmission of the signal can take place via one of these signal paths by means of active and/or passive signal processing means. For example, the signal transmission can take place via at least one amplifier device and/or at least one signal filter device and/or at least one signal switching device.

The circuit arrangement comprises at least one first uplink path for transmitting a first uplink signal. Preferably, the circuit arrangement comprises also at least one further uplink path for transmitting a further uplink signal.

Furthermore, the circuit arrangement comprises a first downlink path for transmitting a first downlink signal. Here, the circuit arrangement can comprise precisely one downlink path. Preferably, however, the circuit arrangement comprises the first downlink path and at least one further downlink path for transmitting a further downlink signal.

A signal path can here be in the form of a frequency range-non-specific signal path or comprise a frequency range-non-specific signal path section. A frequency range-non-specific signal path or section can in this regard be arranged and/or configured such that signals from all downlink or uplink frequency ranges can be transmitted via them.

A signal path can also be in the form of a frequency range-specific signal path or comprise a frequency range-specific signal path section. A frequency range-specific signal path or section can in this regard be arranged and/or configured such that signals from precisely one or from several, but not all, downlink or uplink frequency range(s) can be transmitted via this.

It is furthermore conceivable that a signal path comprises several frequency range-specific signal path sections which are different from another, in particular a section which serves to transmit the signal from precisely one downlink or uplink frequency range, and a further section which serves to transmit a signal from several downlink or uplink frequency ranges.

When a plurality of signal paths is present, these can in particular be arranged and/or configured such that only signals from a first downlink or uplink frequency range can be transmitted via a first signal path and only signals from a further downlink or uplink frequency range can be transmitted via the at least one further signal path, wherein the first and the further frequency range are different frequency ranges. In particular, signals of different standards can thus be transmitted via different signal paths.

In this regard, it is conceivable for a signal path section to form a common path section of signal paths which are different from one another, wherein one such path section is in particular a path section which serves to transmit a signal from several or even all uplink and downlink frequency ranges.

An uplink path or a downlink path can thus in this regard comprise a plurality of path sections. Hereinafter, a path can also describe a partial section of a path.

Signal paths, that is uplink and downlink paths, of the circuit arrangement can here become or stay activated for establishing an activated state and become or stay deactivated for establishing a deactivated state. In an activated state of the signal path, a transmission of an appropriate signal, in particular a signal transmission which is—as will be described in more detail hereinafter—damped to not more than a prescribed extent, via the signal path is possible. In other words, in an activated state of a path, the interface on the terminal side is connected via this signal path with the interface on the antenna side.

In a deactivated state of a signal path, no signal transmission, or no signal transmission which is—as will be described in more detail hereinafter—damped to more than a prescribed extent, via the appropriately deactivated signal path can be possible. In other words, in a deactivated state, the interface on the antenna side cannot be connected to the interface on the antenna side via the deactivated signal path. Thus, no signals, or only—as explained—damped signals can be transmitted via this signal path from the interface on the terminal side to the interface on the antenna side or vice versa.

Furthermore, the circuit arrangement comprises means for providing the uplink signals, particularly from a terminal signal applied to the interface on the terminal side, which in particular can be transmitted from the terminal via the interface on the terminal side to the circuit arrangement. These means can particular be or comprise filter means, power splitters, circulators, a circuit arrangement and/or further means, wherein these means can be arranged and/or configured such that a signal component of the terminal signal with frequencies of an uplink frequency range or of a plurality of uplink frequency ranges is filtered out of the terminal signal. A means for providing can in particular be or comprise a multiplexer. An uplink signal provided in this manner can then be transmitted via an appropriate public path. A means for providing an uplink signal or a part thereof can here also form a means for combining signals, particularly with frequencies from different frequency ranges, furthermore in particular from different download signals.

Correspondingly, the circuit arrangement comprises means for providing the downlink signals, particularly from an antenna signal, wherein the antenna signal describes the signal which is applied to the interface on the antenna side and in particular is received by the antenna and transmitted to the interface on the antenna side. The means can in this regard particularly be arranged and/or configured such that a signal component of the antenna signal with frequencies of a download frequency range or of a plurality of downlink frequency ranges is filtered out of the antenna signal. A downlink signal filtered in this manner can then be transmitted via an appropriate downlink path. A means for providing a downlink signal or a part thereof can here also form a means for combining signals, in particular with frequencies from different frequency ranges, furthermore in particular from different uplink signals.

Furthermore, the circuit arrangement can comprise means for combining signals, in particular signals which can be transmitted via different uplink paths or uplink path sections, which are in particular specific to frequency ranges, or signals which can be transmitted via different downlink paths or downlink path sections, which are in particular specific to frequency ranges.

Furthermore, the circuit arrangement comprises means for detecting at least one uplink signal. The means for detection are here known to the person skilled in the art and are for example described in DE 10 2014 213 933 A1 or in DE 10 2017 209 209 A1. The means for detecting an uplink signal can here also identify an uplink signal, in particular the uplink frequency range of the corresponding uplink signal and/or a transmission standard of the detected uplink signal. As previously described, for identifying a standard, a further signal analysis of the uplink signal can be carried out, for example an analysis of a time behaviour of the uplink signal. It is possible for it to be possible to specify alternatively or cumulatively by a signal analysis, particularly an analysis of the time behaviour, whether an uplink signal is detected according to a TDD method or an FDD method. Appropriate analysis methods are here known to the person skilled in the art.

Furthermore, the circuit arrangement comprises means for establishing an activated state of the uplink path to which the detected (and identified) uplink signal is assigned. An uplink signal can be assigned to an uplink path when the frequency, in particular the carrier frequency, lies in the uplink frequency range to which the uplink path is assigned. In particular, an activated state of an uplink path or uplink path section which is specific to a frequency range can be established. In other words, by means of the means for establishing the activated state, the uplink path can be activated which—as previously explained—is configured for transmitting signals with frequencies from the uplink frequency range, which comprises also the frequency of the detected uplink signal.

According to the disclosure, the circuit arrangement comprises means for establishing a simultaneously activated state of at least two downlink and/or uplink paths which are different from one another, wherein the establishing or the maintaining of this activated state takes place when precisely one uplink signal or several uplink signals is/are detected.

The maintaining of the state can mean that an activated or deactivated state is not altered when this is already been established. E.g., the maintaining of the simultaneously activated state describes that no activated state is established of the signal paths which are in the activated state. Thus, the means for establishing can also be a means for maintaining the simultaneously activated state.

In other words, at least three signal paths, specifically at least one uplink path and at least two downlink paths different from one another, become or remain simultaneously activated. This facilitates in an advantageous manner a simultaneous transmission of several downlink signals with frequencies from downlink frequency ranges which are different from one another. This can also be described as a downlink inter-band carrier aggregation.

It is e.g. possible for an uplink signal to be detected in the previously explained basic state in several or even all download paths are activated. According to the method of the prior art, then a deactivated state of all apart from one download path was established. According to the disclosure, at the detection of an uplink signal, now the activated state of at least two or even all downlink paths are maintained.

Thus, the circuit arrangement is in particular configured such that the establishing or the maintaining of the explained activated state of at least two downlink paths (different from one another) takes place when precisely one uplink signal or several uplink signals is/are detected.

The establishing/maintaining of a simultaneously activated state of at least two downlink paths can in particular take place in that an activated state of at least one common path section of the downlink paths or in that an activated state of at least one path section of the first downlink path as well as an activated state of at least one path section of the further downlink path is established or maintained.

Of course, the circuit arrangement can also comprise means for establishing or maintaining a deactivated state of the signal paths. E.g., the means for establishing an activated state can also serve to establish or maintain a deactivated state.

The circuit arrangement can here comprise at least one means for establishing an activated state by means of which precisely one signal path can be activated. Alternatively or cumulatively, the circuit arrangement can comprise at least one means for establishing an activated state by means of which several signal paths can be activated simultaneously.

Thus, in an advantageous manner, a data throughput rate in the transmission of downlink signals via the proposed circuit arrangement can be increased, in particular when transmitting signals according to 3G, 4G or 5G standard. Further, for example, it is possible that a downlink path for transmitting downlink signals according to a 5G standard and a further downlink path transmitting downlink signals according to the 4G standard and thereby in the appropriate receiving bands is activated and thus a simultaneous data transmission according to both standards can take place. As a result, in an advantageous manner, an increase of the data throughput rate, which can also be described as a so-called data boost, can be the result, and a data transmission according to the NSA mode (non stand alone mode) of the 5G standard can be facilitated. In turn, this facilitates in an advantageous manner e.g. a more rapid or improved implementation of applications which are based on these transmitted data.

Alternatively or cumulatively, the circuit arrangement comprises at least one further uplink path transmitting a further uplink signal as well as means for publishing a simultaneously activated state of at least two uplink paths. An activated state of the at least two uplink paths is established or maintained when one, particularly precisely one, uplink signal is detected, or when at least two uplink signals which are particularly different from one another are detected. This can also be described as uplink inter-band carrier aggregation when these at least two uplink signals are transmitted by a terminal. However, it is also conceivable for the at least two uplink signals be transmitted from at least two different terminals.

Thus, the circuit arrangement is in particular configured such that the establishing or the maintaining of the explained activated state of at least two uplink paths (different from one another) takes place when at least one uplink signal is detected.

In this regard, the establishing or maintaining of the simultaneously activated state of at least two uplink paths can take place as a function of a previously known arrangement between different uplink signals and activation states, assigned to these different uplink signals, of several uplink paths. In other words, when an activated uplink signal is detected, at least one further uplink path for transmitting a further uplink signal, which however does not necessarily also need to be detected, can be activated, or its activated state can be maintained, as a function of a previously known assignment.

Hereinafter, explanations regarding the establishing of an activated state or the activation apply also for the maintaining of the activated state.

It is e.g. conceivable for the activated state of several uplink paths to be established such that for each activated downlink path with the uplink paths activated in such a manner an FDD-based signal transmission facilitated. In other words, an activated state of several receiving paths and several uplink paths can be established such that all activated downlink paths serve for FDD-based signal transmission and/or all activated uplink paths serve for FDD-based signal transmission.

Regarding the establishing of the activated state of uplink paths, the in this disclosure regarding the downlink paths apply mutatis mutandis. In particular, the means for activating can comprise also at least one activatable amplifier device and/or at least one switching device.

Thus, in an advantageous manner, a data throughput rate in the transmission of uplink signals via the proposed circuit arrangement can be increased, in particular when transmitting signals according to 3G, 4G or 5G standard. Furthermore, it is e.g. possible for an uplink path for transmitting uplink signals according to a 5G standard and a further uplink path for transmitting uplink signals according to 4G standard to be activated and thereby for a simultaneous data transmission according to both standards to be able to take place. Thus, in an advantageous manner, an increase in the data throughput rate for uplink signals, which can also be described as a so-called data boost, can take place and a data transmission according to the explained NSA mode (non stand alone mode) can be facilitated.

It is possible for the means for activating an uplink path to form at least a part of a means for activating a downlink path, or vice versa. It is furthermore possible for the means for providing a downlink signal to form at least a part of a means for providing an uplink signal, or vice versa.

It is furthermore possible for means for activating to form also part of a means for providing, or vice versa, particularly a switching device.

Switching device can in particular comprise at least one control and evaluating device, wherein this comprises a computing device or can be in the form of a computing device. In turn, the computing device can be designed e.g. as a microcontroller or an integrated circuit or comprise one such. The previously explained means for detecting at least one uplink signal and the means for establishing an activated state can here comprise the control and evaluating device or can be completely or at least partially formed by this.

In the activated state of a signal path, a size of the output signal of the signal path can be greater than or not substantially smaller than the size of the input signal. The ratio of input to output power of a signal path can be described as an amplification of the signal path, wherein a negative amplification corresponds to a signal damping. E.g., an activated path can have an amplification dimension G (amplification factor A) which is greater than or equal to G=16 dB (A=40), 27 dB (A=500) or 50 dB (A=100000). It is furthermore possible for a signal path in a bypass state, which can also be an activated state, to have an amplification dimension G (amplification factor A) which is greater than or equal to G=−3 dB (A=0.5) or −6 dB (A=0.25).

In a deactivated state of the signal path, an amplification dimension G (amplification factor A) can be less than or equal to G=−20 dB (A= 1/100), G=−50 dB (A= 1/100000) or G=−100 dB (A=exp (−10)).

It is furthermore possible for an amplification dimension G of a signal path in the activated state to be greater by at least 10 dB, 20 dB or 40 dB than in a deactivated state.

For establishing an activated state of a signal path, the amplifier device can be activated or remain activated in the signal path. It is for example possible for an amplifier device to be arranged in an activatable signal path and thus for the signal transmission via the signal path to be able to take place via this amplifier device.

Alternatively or cumulatively to the establishing of an activated state of an amplifier device, also further methods for establishing an activated or deactivated state of a signal path can be used.

An activated or deactivated state of the signal path can for example be established by switching on and switching off, in particular also by establishing or interrupting a power supply, an amplifier device and/or by altering the amplification factor of an amplifier device and/or by establishing or interrupting a signal path for signal connection e.g. by means of HF switches and/or by altering a damping factor of a damping device and/or by altering a useful frequency (range) of a filter device.

In a further embodiment, an activated uplink path and one of the activated downlink paths serve for FDD-based signal transmission. In other words, the activated uplink path and precisely one of the activated downlink paths can facilitate a signal transmission in an FDD band according to an FDD standard.

In the FDD-based signal transmission, the transmission of signals is carried out with two uplink and downlink frequency ranges which are different from one another and assigned to one another.

In other words, thus a state of the switching arrangement can be established in which a signal transmission can be carried out according to a desired FDD standard, wherein additionally a further downlink signal from a further downlink frequency range can be transmitted.

Thus, this results in an advantageous way in a data throughput rate for downlink signals being able to be increased.

In a further embodiment, the establishing or maintaining of the simultaneously activated state of at least two downlink paths takes place as a function of a previously known assignment between two different uplink signals, i.e. uplink signals from different uplink frequency ranges, and downlink paths assigned to these different uplink signals.

Thus, a first set of downlink paths can be assigned to an uplink signal from a first uplink frequency range, wherein, when an uplink signal of this sort is detected, an activated state of all downlink paths of the first set is established. A further set of downlink paths can be assigned to a further uplink signal wherein the further set of downlink paths can differ from the first set of downlink paths. This can in particular mean that the further set comprises more downlink paths than the first set, fewer downlink paths than the first set and/or at least one downlink path which is not a component of the first set. When the uplink signal is a signal for an FDD-based signal transmission, thus the set of downlink paths assigned to this uplink signal comprises preferably the downlink path for FDD-based signal transmission in the frequency ranges of an FDD band.

Thus, this results in an advantageous way in a simple adaptation to previously determined uplink and receiving scenarios, which can for example be predetermined by regulatory specifications or technical possibilities of the terminal and/or of the base station. Here, the assignment can be an adaptive assignment. This can mean that the assignment can be changed, in particular also after starting up the circuit arrangement.

In a further embodiment, the downlink frequency ranges of at least two of the downlink signals which can be transmitted via the downlink paths are assigned to a first downlink frequency range set, wherein the establishing or the maintaining of the activated state of the downlink paths takes place such that a downlink signal from one of the frequency ranges of the first downlink frequency range set and at least one downlink signal from a downlink frequency range which is not assigned to the first downlink frequency range set can be transferred.

A downlink frequency range set can here comprise one or at least two downlink frequency ranges, in particular downlink frequency ranges which are directly adjacent in the frequency range. For example, a first downlink frequency range set can be a so-called low band range, wherein this comprises frequencies of 500 MHz to 1000 MHz. A further downlink frequency range set can be a so-called mid band range, which comprises frequencies from 1700 MHz to 2400 MHz and a further downlink frequency range set can be a so-called high band range which comprises frequencies from 2500 MHz to 4000 MHz. In particular, the individual sets can comprise different amounts of downlink frequency ranges.

It is possible for at least one of the downlink frequency range sets to be assigned to at least two downlink frequency ranges, wherein to each further downlink frequency range set can be assigned precisely one or also several downlink frequency range(s). Preferably, at least two downlink frequency ranges are assigned to each downlink frequency range set.

It is e.g. conceivable for the establishing of the activated state of the downlink paths to take place such that one of the downlink signals from a downlink frequency range set to which at least two downlink signals are assigned, as well as the downlink signals which are assigned to the further downlink frequency range quantities, can be transmitted. Here, a downlink signal is assigned to a downlink frequency range set when the frequency of the downlink signal is situated in one of the frequency ranges of this set.

If, for example, an uplink signal is detected to which, according to an FDD-based transmission method, a downlink signal from a first downlink frequency range set, e.g. the low band range, is assigned, thus the establishing of the activated state can take place such that the activated state of the downlink path assigned to this downlink signal as well as the activated state of all downlink paths of the further downlink frequency range sets, for example thus of the high band range, is established.

The circuit arrangement can for example comprise a means for establishing an activated state of all signal paths of a set of signal paths, that is e.g. of the signal paths for transmitting signals from the low band range, the mid band range and/or the high band range.

If, in contrast, an uplink signal is detected, to which, according to an FDD-based transmission method, a downlink signal from the high band range is assigned, thus the establishing of the activated state can take place such that the activated state of the downlink path assigned to this downlink signal as well as the activated state of all downlink paths of the further downlink frequency range sets, for example thus of the low band range, is established.

Thus, this results in an advantageous way in simplified handover possibilities between the mobile radio bands e.g. from a low band-based signal transmission to a high band-based signal transmission, since e.g. a terminal furthermore is able to receive a signal with frequencies from the high band frequency range although a low band uplink signal is detected. In a further advantageous manner, the combining of several downlink frequency ranges to form a downlink frequency range set and selection of only one band reduces the circuit effort, since frequency ranges which lie close together can be separated by complex circuitry. It results also in an advantageous manner that by means of the proposed circuit arrangement, specifications regarding possible band combinations, e.g. within the ETSI standard, can be fulfilled.

Furthermore, in an advantageous manner, an adaptation of the circuit arrangement to the signal transmissions supported by the network providers or terminals can take place.

In a further embodiment, the establishing or maintaining of an activated state of the downlink paths takes place such that several, but not all downlink signals which are not assigned to the first downlink frequency range set, can be transmitted. In particular, selected downlink signals from further downlink frequency range sets can be transmittable, e.g. precisely one or at least one downlink signal from each of the further downlink frequency range sets.

Alternatively, establishing or maintaining takes place such that all downlink signals can be transmitted which are not assigned to the first downlink frequency range set.

Thus, this results in an advantageous way in the previously explained compatibility with guidelines, the reduced circuit effort for separating frequency bands and the adaptation of the circuit arrangement to the signal transmission carried out by a mobile radio cell or by a terminal.

In a further embodiment, the means for providing the downlink signals and/or the means for providing the uplink signals comprise each case at least one filter means. A filter means can in particular be a filter device, for example a low pass filter, a bandpass filter, a band stop filter or a high pass filter, a combination of these filters or a further filter device.

The filter means can in particular be configured such that signals of precisely one uplink frequency range or precisely one downlink frequency range can be provided or be filtered as an output signal of the filter means from an input signal of the filter means. A filter means of this sort serves thus for providing a signal which is transmitted via a frequency range-specific signal path or signal path section. Thus, a signal path or signal path section of this sort can comprise a filter means of this sort.

It is also possible for a filter means to be designed such that an output signal of the filter means comprises frequencies of several uplink frequency ranges or downlink frequency ranges. These several frequency ranges can be in the spectrum or frequency curve of adjacent ranges.

A filter means of this sort serves to provide a signal which is transmitted via a frequency range-non-specific signal path or signal path section. Thus, a signal path or signal path section of this sort can comprise a filter means of this sort.

It is also possible for at least two or several of the previously described filter means to be arranged in a downlink path or an uplink path.

In particular, a filter means can be designed as a frequency multiplexer or the formed by a frequency multiplexer, wherein this frequency multiplexer serves for a frequency-selective division of an input signal into precisely two or more than two output signals of the frequency multiplexer. A frequency multiplexer divides in particular an input signal containing/comprising different frequencies into two or more output signals, which in each case comprise different partial ranges of the frequency range of the input signal. Furthermore, the frequency multiplexer can however also serve to combine precisely two or more than two input signals of different frequency ranges to form precisely one output signal. E.g., a frequency multiplexer of this sort can be designed as a so-called diplexer, triplexer, quadplexer, hexaplexer etc.

Alternatively or cumulatively, the means for providing the downlink signals and/or the means for providing the uplink signals comprise(s) in each case at least one power splitter. A power splitter can also be described as a splitter. By means of the power splitter, an input signal with an input signal power can be divided into two or more than two output signals, the output signal powers of which is in each case a predetermined proportion of the input signal power. Here, each of the output signals can comprise the same frequency range as the input signal. Furthermore, the power splitter can however also serve to combine precisely two or more than two input signals to form precisely one output signal, wherein the output signal power is then equal to the sum of the input signal powers. In this case, the power splitter can also be described as a combiner.

Analogously to the previous description with regards to the filter means, at least one power splitter, or several power splitters, can be arranged in an uplink path or downlink path.

It is furthermore conceivable for a filter means and/or a power splitter to be arranged in several downlink paths or uplink paths, in particular in a common path section of these several uplink and downlink paths.

This results in an advantageous manner in a reliable provision of desired uplink or downlink signals, wherein a signal damping is reduced and installation space requirements as well as manufacturing costs are reduced in comparison to solutions with discrete components.

In a further embodiment, an interface, on the antenna side, of the circuit arrangement is connected to a signal connection, on the antenna side, of the means for providing the downlink signals. The means for providing is here designed as a filter means or comprises at least one filter means. The means for providing, particularly however also the filter means, can, as previously explained, also serve to combine uplink signals. Furthermore, this signal connection on the antenna side is formed by a signal connection, on the antenna side, of the filter means for providing the downlink signals. Thus, the signal connection, on the antenna side, of the filter can be connected immediately or directly however, it is also conceivable for the signal connection, on the antenna side, of the filter means to be connected via, for example, a directional coupler to the signal interface, on the antenna side, of the circuit arrangement.

In other words, in receiving direction starting from the interface on the antenna side, the filter means is the first element of the means for providing the downlink signals.

It is possible for the means for providing to comprise further means, e.g. a switching device. In this case, this switching device is connected via the filter means to the signal connection, on the antenna side, of the circuit arrangement. Thus, in this case, the switching device is not connected immediately or directly to the signal interface, on the antenna side, of the circuit arrangement.

Thus there results in an advantageous manner a low-damping division of a signal transmitted from the interface on the antenna side to the means for providing the downlink signals, that is in downlink direction, into different frequencies or frequency range or a low-damping transmission of signals in uplink direction, in order in particular to facilitate the described transmission of signals via several signal paths activated independently of one another and therewith the carrier aggregation. In turn, this facilitates also the previously described improved possibility of handover.

In a further embodiment, the means for establishing or maintaining the activated state, in particular the simultaneously activated state, comprise at least one activatable or controllable amplifier device and/or at least one controllable damping device.

It is for example possible for at least one activatable or controllable amplifier device and/or damping device to be arranged in each downlink path. This was already described previously. It is also conceivable for an activatable or controllable amplifier device and/or damping device to be arranged in several downlink paths, in particular in a common section of these several downlink paths. For establishing the activated state of one or more downlink path(s), the amplifier and/or damping device or the amplifier and/or damping device(s)—as previously explained—can be activated, or their amplifying factors and/or damping factors can be adjusted.

Correspondingly, in each case one activatable or controllable amplifier device and/or damping device can be arranged also in each uplink path. Alternatively, an activatable or controllable amplifier device and/or damping device can be arranged in several uplink paths, for example in a common section of these several uplink paths.

An operation of an activatable or controllable amplifier device and/or damping device can here be controlled particularly by the previously explained control and evaluating device. To this end, the control and evaluating device can be connected using signal and/or data technology with the activatable amplifier device and/or damping device.

This results in an advantageous manner in an establishing of an activated state of signal paths which is easy to implement. In particular, a targeted activation can take place, as a result of which a multiplicity of operational scenarios, in particular a multiplicity of different downlink carrier aggregation states, can be set in an advantageous manner.

In a further embodiment, the means for activating comprise at least one switching device. A switching device can for example be in the form of a HF disconnector. A HF disconnector can for example be designed as a SPST (single pole single throw) switch.

In this regard, an opened or closed state of the HF disconnector can be set. In the opened state, a signal transmission via the disconnector is not possible. In the closed state, a signal transmission via the HF disconnector is possible. The establishing of an activated state can take place, for example, in that an HF disconnector which is arranged in at least one signal path is closed. Correspondingly, a deactivated state can be established when the HF disconnector is opened.

The switching device can also be in the form of an HF changeover switch. An HF changeover switch can for example be designed as an SPDT (single pole double throw) switch, as a SP3T switch or an alternatively designed switch. Here, an input connection of the HF changeover switch in various switching states of the HF changeover switch can be connected to various output connections of the changeover switch, wherein the input connection in a switching state can preferably be connected to precisely one output connection.

In a switching state change, thus the connection between the input connection and an output connection which was hitherto connected thereto can be separated and simultaneously a connection of the input connection to a further output connection can be closed.

When a signal path is connected with one of the output connection of an HF changeover switch, thus the establishing of an activated state of the signal path can take place in that a switching state of the HF changeover switch arranged in the signal path is adjusted such that the input connection of the HF changeover switch is connected to the output connection to which the signal path is connected.

In this case, at least one further signal path can be activated simultaneously. The establishing of a deactivated state can take place in that a switching state of the HF changeover switch arranged in the signal path is adjusted such that the connection state of the HF changeover switch arranged in the signal path is adjusted such that the input connection of the HF changeover switch is connected to a further output connection to which the signal path is not connected. In this case, simultaneously at least one further signal path can be deactivated.

The circuit arrangement can however additionally also comprise HF changeover switches which in a switching state connect an input connection simultaneously to at least two output connections. An HF changeover switch of this sort can for example form a power splitter.

The operation of the at least one switching device, thus, in particular the setting of different switching states of the switching device, can here be controlled by the previously described control and evaluating device. To this end, the control and evaluating device can be connected to the at least one switching device using data and/or signal technology.

Also in this embodiment, there results in an advantageous manner a simple way of creating activated states of different signal paths which is reliable and simple to implement.

In a further embodiment, the circuit arrangement comprises means for detecting several simultaneously transmitted uplink signals or means for detecting a further uplink signal, when an uplink signal has already been detected and/or when an uplink path has already been activated. Appropriate means are disclosed in DE 10 2017 219 690 A1, in particularly in claim 15 and paragraphs [0013] and [0029], wherein uplink signals are described as transmission signals of the terminal. When a further uplink signal of this sort is detected, thus the uplink path assigned to this further uplink signal can be activated. Uplink signals which have been transmitted simultaneously can in particular be signals which are transmitted via different but simultaneously activated signal paths, in particular in different uplink frequency ranges. In other words, it is made possible for uplink signals in different uplink frequency ranges to be able to be detected without interrupting or negatively influencing active uplink and downlink paths. Preferably, the detection of state alterations is carried out e.g. by changing uplink frequency ranges or by activating/deactivating signal paths at a speed at which data transmission losses are minimised by an activation of signal paths which is contingent on the state change.

In a further embodiment, an activated state of the uplink paths required for transmitting all detected uplink signals is established or maintained. Furthermore, an activated state of downlink paths is established or maintained such that an FDD-based signal transmission is facilitated in the activated uplink and downlink paths.

In other words, thus the downlink paths can be activated by means of which downlink signals can be transmitted on the downlink frequency ranges which form a frequency range pair for an FDD-based signal transmission with the uplink frequency ranges to which the detected uplink signals are assigned. Thus, for each detected uplink signal is facilitated an FDD-based signal transmission which is then effected via this uplink signal and the corresponding downlink signal.

Thus, in an advantageous manner, a data throughput rate in the transmission of uplink and downlink signals via the proposed circuit arrangement can be increased.

In a further embodiment, the circuit arrangement comprises a signal path for transmitting signals according to a time-duplex method (TDD). It thus results in an advantageous manner that the circuit arrangement is also able to transmit signals according to a time-duplex method, as a result of which the applicability of the circuit arrangement is advantageously increased.

In a time-duplex method, the uplink and downlink signals are transmitted separately in time, preferably, however, in the same frequency range. In an advantageous embodiment, the uplink and downlink signal paths can be activated and deactivated in a temporally antiparallel sense. In other words, the uplink signal path is deactivated when the corresponding downlink signal path is activated. When an uplink signal is detected and the corresponding uplink path activated, at least this downlink path, which is able to serve particularly to transmit signals from the same frequency range, is deactivated. In particular, the completely deactivated state of the downlink path can be established chronologically prior to the completely activated state of the uplink path or vice versa. Thus, in an advantageous manner, signal distortions and loop oscillations are avoided. Furthermore, the efficiency is increased, since circuit parts which are not used can be turned off.

It is e.g. possible for the signal path for transmitting signals according to a time-duplex method to be activated as a further uplink path.

In a further embodiment, a time-duplex based signal can be detected. The time-duplex based signal can in particular be an uplink signal.

Furthermore, an activated state of the uplink path and a deactivated state of the downlink path, to which the detected time-duplex based signal is assigned, can be established. In particular, the completely deactivated state of the downlink path can be established chronologically prior to the completely activated state.

The transmission of uplink and downlink signals according to a time-duplex method takes place in the same frequency range. Thus, particularly a deactivated state of the downlink path can be established which serves to transmit signals from this frequency range.

Furthermore, at least one section of an uplink signal path for TDD signal transmission can also form a section of a downlink signal path for TDD signal transmission. This at least one section can then be used alternatingly for downlink and uplink signal transmission. A corresponding switching can be effected by means corresponding the control. It is thus possible for only one, instead of several, signal line to be used for downlink and uplink signal transmission. In particular an activation of an uplink signal transmission can be effected when a TDD uplink signal is detected.

In particular, an amplifier device for amplification for a TDD uplink signal can also form an amplifier device for a TDD downlink signal. For transmitting the different signals, an amplifier device can be switched over. In particular, an activation of the amplification device can take place in an uplink signal amplification mode when a TDD uplink signal is detected.

As a result, circuit complexity is reduced in an advantageous manner.

Furthermore, an activated state of at least one further downlink path, which are different from this deactivated downlink path, can be established, or this at least one further downlink path can remain activated.

Furthermore, also an activated state of at least one further uplink path, which are different from this deactivated uplink path, can be established, or this at least one further uplink path can remain activated.

Corresponding advantages were listed previously.

Furthermore proposed is a method for operating a circuit arrangement for transmitting uplink and downlink signals between at least one terminal and at least one antenna. The circuit arrangement can be designed according to one of the embodiments described in this disclosure. Thus, the explained circuit arrangement can in particular be configured such that a method of this sort can be carried out using the circuit arrangement.

According to the disclosure, it is verified whether at least one uplink signal is present. Furthermore, a simultaneously activated state of at least two downlink paths is established or maintained when an uplink signal is detected. In particular, but not obligatorily, the two downlink paths can be activated simultaneously. However, for establishing the activated state, it is also possible for the activation, that is the transfer into the activated state, to take place sequentially. Alternatively or cumulatively, a simultaneously activated state of at least two uplink paths is established or maintained when the uplink signal or when at least one further uplink signal is detected. These and corresponding advantages were previously already explained.

The fact that a simultaneously activated state of at least two signal paths is established comprises also the embodiment that an existing simultaneously activated state of at least two signal paths is maintained.

In a further embodiment, the establishing or maintaining of the activated state of the downlink path or an uplink path is carried out by activating and amplifying device. This was previously already explained. Alternatively or cumulatively, the establishing or maintaining of the activated state of an uplink path downlink path is carried out by switching/controlling a switching device, that is by adjusting or retaining a switching state assigned to the activated state. In particular, thus, the establishing can take place according to the previously explained embodiments. The corresponding advantages were also previously explained.

The disclosure will be explained in more detail with reference to embodiment examples. The figures show in:

### BRIEF DESCRIPTION OF THE DRAWINGS

FIG. 1 a schematic block diagram of a circuit arrangement according to the disclosure,

FIG. 2 a schematic block diagram of a circuit arrangement according to the disclosure in a further embodiment,

FIG. 3 a schematic diagram of a circuit arrangement according to the disclosure in a further embodiment,

FIG. 4 a schematic block diagram of the circuit arrangement shown in FIG. 3 in a further embodiment,

FIG. 5 a schematic flow diagram of a method according to the disclosure,

FIG. 6 a schematic flow diagram of a method according to the disclosure in a further embodiment,

FIG. 7 a schematic flow diagram of a method according to the disclosure in a further embodiment,

FIG. 8 a schematic representation of a transmission behaviour of the circuit arrangement in the frequency range and

FIG. 9 a further schematic representation of the transmission behaviour of the circuit arrangement in the frequency range.

### DETAILED DESCRIPTION OF THE PREFERRED EMBODIMENTS

Hereinafter, identical reference signs describe elements with identical or similar technical properties.

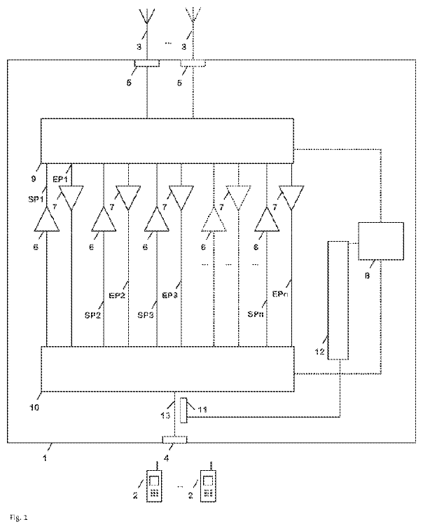

FIG. 1 shows a schematic block diagram of a circuit arrangement 1 for transmitting uplink and downlink signals between at least one terminal 2 and at least one antenna 3. Here, in FIG. 1, two terminals 2 and two antennas 3 are shown in an exemplary manner, wherein the circuit arrangement is able to transmit uplink and downlink signals between these terminals 2 and the antennas 3.

The circuit arrangement 1 comprises at least one interface 4 on the terminal side, which facilitates a wireless or cable signal connection between the terminal 2 and the circuit arrangement 1. Furthermore, the circuit arrangement 1 comprises at least one interface 5 on the antenna side to which the at least one antenna 3 is connected using signal technology.

It is further shown that the circuit arrangement 1 comprises several uplink paths SP1, . . . , SPn, wherein a first uplink path SP1, a second uplink path SP2, a third uplink path SP3 and an nth uplink path SPn are shown. Correspondingly, the circuit arrangement comprises several downlink paths EP1, . . . , EPn, wherein a first downlink path EP1, a second downlink path EP2, a third downlink path EP3 and an nth downlink path EPn are shown.

The shown uplink paths SP1, . . . , SPn can in particular be frequency range-specific uplink paths. The shown downlink paths EP1, . . . , EPn can in particular be frequency range-non-specific downlink paths. A path can also describe a path section of a path, wherein this path can comprise several path sections.

For example, via the first uplink path SP1, signals from a frequency range of 832 MHz to 862 MHz (first uplink frequency range, FDD mobile radio band 20) and via the first downlink path EP1, signals from the frequency range 791 MHz to 821 MHz (first downlink frequency range, FDD mobile radio band 20) can be transmitted. For example, via the second uplink path SP2, signals from a frequency range from 880 MHz 915 MHz (second uplink frequency range, FDD mobile radio band 8) and via the second downlink path EP2, signals from the frequency range 925 MHz to 960 MHz (second downlink frequency range, FDD mobile radio band 8) can be transmitted. For example, via the third uplink path SP3, signals from the frequency range 2570 MHz to 2620 MHz (third uplink frequency range, TDD mobile radio band 38), and via the third downlink path EP3, signals from the frequency range 2570 MHz to 2620 MHz (third downlink frequency range, TDD mobile radio band 38) can be transmitted. The further signal paths can be configured correspondingly for transmitting signals from further mobile radio bands (for example band 1, band 3, band 5, band 40 or others).

In this regard, in the uplink paths SP1, . . . , SPn are arranged activatable uplink amplifier devices 6. In each of the downlink paths EP1, . . . , EPn is arranged respectively one activatable downlink reception amplifier device 7. By means of the uplink amplifier device 6, thus an uplink signal transmitted via the appropriate uplink path SP1, . . . , SPn, which is transmitted from the interface 4 on the terminal side the interface 5 on the antenna side, can be amplified. Correspondingly, by means of the downlink amplifier devices 7, a downlink signal, which is transmitted from the interface 5, on the antenna side, of the circuit arrangement 1 to the interface 4 on the terminal side, can be amplified.

The amplifier devices 6, 7 serve here for activating and deactivating the shown signal paths SP1, . . . , SP5, EP1, . . . , EP5. It is of course also conceivable for the activating and deactivating to be carried out by other means.

It is shown that the amplifier devices 6, 7 are arranged respectively in a frequency range-specific section of uplink paths SP1, SP2, . . . , SPn or downlink paths EP1, . . . , EPn, wherein these frequency range-specific sections serve in each case for transmitting uplink or downlink signals from precisely one uplink or downlink frequency range.

Further shown is a control and evaluating device 8 of the circuit arrangement 1. This can be in the form of a microcontroller. The activatable uplink and downlink amplifier devices 6, 7, in particular their operation, can be controlled by means of the control and evaluating device 8. In particular, an uplink or receiving amplifier device 6, 7 can be able to be deactivated by means of the control and evaluating device.

In the activated state of an amplifier device 6, 7, the corresponding signal path is activated and a signal transmission via the appropriate uplink or downlink path SP1, . . . , SP5, EP1, . . . , EP5 is possible, in particular with a desired amplification. In particular, an amplification factor of the amplifier devices 6, 7 can be predetermined or adjustable in the activated state.

It is further shown that the circuit arrangement 1 contains multiplexers 9, 10 for providing uplink and downlink paths 9, 10, wherein a first multiplexer 9 can be described as a multiplexer on the antenna side and a further multiplexer 10 as a multiplexer on the terminal side. The first multiplexer 9 can here serve as a frequency splitter. In particular, the first multiplexer 9 can comprise a plurality of filter devices, in particular low pass filter devices, a plurality of bandpass filter devices and high pass filter devices as well as power splitters, switches, circulators or further elements e.g. elements designed as duplexers, diplexers, triplexers etc., wherein by means of these elements the downlink signals which are to be transmitted by the downlink paths EP1, . . . , EPn can be filtered out of an antenna signal applied to the interface 5 on the antenna side. This antenna signal can e.g. be transmitted from a base station and received by one of the, or the two, antennas 3.

The first multiplexer 9 can also serve as a signal combiner. Thus, the uplink signals transmitted via the uplink paths SP1, . . . , SPn can be combined to form at least one resulting signal which is then transmitted to the interface(s) 5 on the antenna side. This resulting signal can then be sent by an antenna 3 e.g. to the described base station.

The further multiplexer 10 can here serve as a frequency splitter. In particular, also the further multiplexer 10 can comprise a plurality of filter devices, in particular low pass filter devices, a plurality of bandpass filter devices and high pass filter devices as well as power splitters, switches, circulators or further elements e.g. elements designed as duplexers, diplexers, triplexers etc., wherein by means of these elements the uplink signals which are to be transmitted by the uplink paths SP1, . . . , SPn can be filtered out of at least one terminal signal applied to the interface 4 on the terminal side. This terminal signal can e.g. be sent from the terminal 2 and transmitted by the interface 4 on the terminal side.

It is also possible for the further multiplexer 10 serve as a signal combiner. Thus, the downlink signals transmitted via the downlink paths EP1, EPn can be combined to form at least one resulting signal which is then transmitted to the interface 4 on the terminal side. This resulting signal can then be transmitted from the interface 4 on the terminal side to the terminal 2.

It is further shown that the circuit arrangement comprises a signal decoupling device 11 and a device 12 for uplink signal detection connected with signal technology to the signal decoupling device 11. The device 12 for uplink signal detection is here connected to the control and evaluating device 8. The device 12 for uplink signal detection is coupled with signal technology via the signal decoupling device 11, which can for example be designed as a directional coupler or power splitter, to a connecting signal path 13, wherein the connecting signal path 13 connects the interface 4 on the terminal side to the further multiplexer 10, in particular its output connection. The connecting signal path 13 can here form a section of a downlink signal path or of an uplink signal path, wherein this section can be in the form of a frequency range-non-specific, that is broadband, signal path section. By means of the device 12 for uplink signal detection, it can be detected whether one or several uplink signal(s) is/are applied to the connecting signal path 13 and thereby also to the interface 4 on the terminal side. The embodiment shown in FIG. 1 for detecting/identifying an uplink signal is here only exemplary. Of course, alternative or additional means/devices and circuit arrangements can be used within the proposed circuit arrangement for detection/identification.

This uplink signal can in particular be a signal generated by the terminal 2 and received by the interface 4 on the terminal side. Furthermore, by means of the device 12 detecting transmission activity, the uplink signal, in particular the uplink frequency range and/or the transmission standard of the uplink signal, can be identified.

If, for example, an uplink signal from a first uplink frequency range is detected and identified, thus, in particular by means of the control and evaluating device 8, the uplink amplifier device 6 in the first uplink path SP1 is activated or the activation is maintained. Thus, an activated state of the first uplink path SP1 is established or maintained, that is, is not deactivated.

Furthermore, the downlink amplifier device 7 in the first downlink path EP1 and at least one, several, but not all, or all of the downlink amplifier devices 7 of the further shown downlink paths EP2, EP3, EPn can be activated or remain activated.

It is possible for the activation or deactivation of the downlink amplifier devices 7 to be carried out, depending on a previously known assignment between different uplink signals and downlink paths EP1, . . . , EPn to be activated which are assigned to these different uplink signals, by means of the control and evaluating device 8, wherein when an uplink signal is detected, the control and evaluating device 8 activates both the corresponding uplink amplifier device 6 as well as the downlink amplifier devices 7 assigned to this uplink signal. The assignment can here be stored e.g. in a not shown storage device of the circuit arrangement 1, in particular of the control and evaluating device 8.

It is furthermore possible that, when an uplink signal has already been detected, a further uplink amplification device 6 is activated or the corresponding activation is maintained, in particular by means of the control and evaluating device 8.

Thus, it is for example conceivable for two or more uplink amplifier devices 6 to become or remain activated when precisely one uplink signal is detected by means of the device 12 for uplink signal detection. However, it is further possible for at least one uplink amplifier device to be deactivated in a case of this sort.

Preferably, however, it can be detected by means of the device 12 for uplink signal detection when, simultaneously with at least one already detected uplink signal, a further uplink signal is applied to the connection signal path 13. When one such further uplink signal is detected and identified, then the uplink amplifier device 6 in the uplink path SP1, . . . , SP5 of the uplink path SP1, . . . , SPn assigned to this further uplink signal can become or remain activated, particularly by means of the control and evaluating device 8.

Thus, the device 12 for uplink signal detection shown in FIG. 1 can also be in the form of a device for the simultaneous detection of a plurality of uplink signals. Of course, however, the circuit arrangement 1 can also contain one or several further (not shown) device(s) for uplink signal detection.

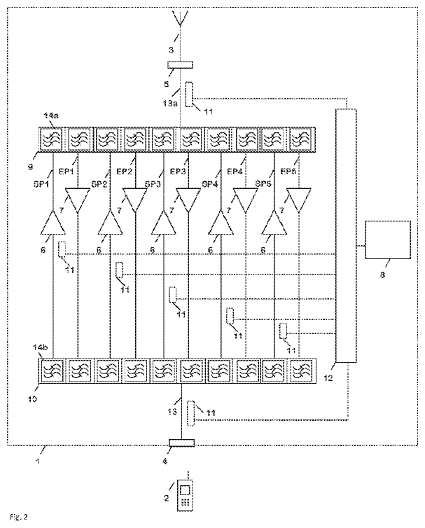

FIG. 2 shows a schematic block diagram of a circuit arrangement 1 for transmitting uplink and downlink signals between at least one terminal 2 and at least one antenna 3 in a further embodiment. Here, in FIG. 2, only one terminal and one antenna 3 are shown, wherein the circuit arrangement is able to transmit uplink and downlink signals between this terminal 2 and the antenna 3.

The circuit arrangement 1 shown in FIG. 2 is in this regard designed substantially like the circuit arrangement 1 shown in FIG. 1. For this reason, reference is made to the corresponding descriptions regarding FIG. 1. In contrast to the embodiment shown in FIG. 1, the antenna 3 is a part of the circuit arrangement 1, i.e. the circuit arrangement 1 includes the antenna 3.

It is further shown that the circuit arrangement comprises five uplink signal paths SP1, . . . , SP5 and five downlink signal paths EP1, . . . , EP5.

It is further shown that the signal decoupling device 11 can be arranged at different positions within the circuit arrangement. It is e.g. possible for the signal coupling device 11 to be arranged and/or configured such that a signal is decoupled from a further connecting signal path 13a, wherein this further connecting signal path 13a connects the interface 5 on the antenna side to the first multiplexer 9. Furthermore, it is possible for a plurality of signal coupling devices 11 to be arranged and/or configured such that signals are decoupled from the sections of the uplink signal paths SP1, . . . , SP5 which connect the further multiplexer 10 to the uplink amplifier devices 6.

It is further shown that the first multiplexer 9 is configured as a filter multiplexer which comprises a plurality of filter devices 14a, whereby for reasons of clarity only one filter device 14a is labelled with a reference sign. A filter device 14a can here be in the form of e.g. a low pass filter device, bandpass filter device or high pass filter device.

Also the further multiplexer 10 is configured as a filter multiplexer which comprises a plurality of filter devices 14b, whereby for reasons of clarity only one filter device 14b is labelled with the reference sign. A filter device 14b can here be in the form of e.g. a low pass filter device, bandpass filter device or high pass filter device. As previously explained, the multiplexers 9, 10 are configured to provide the uplink and downlink signals which are transmitted via the corresponding paths SP1, . . . , SP5, EP1, . . . , EP5, or to combine these signals.

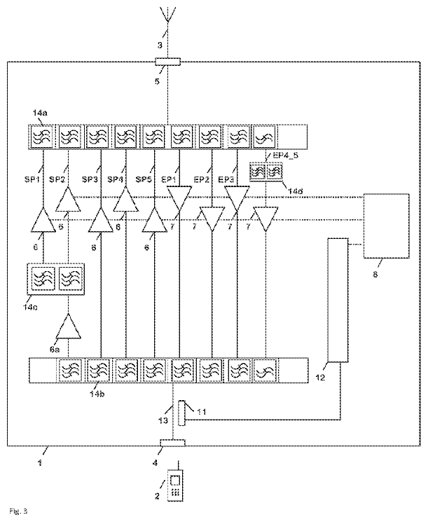

FIG. 3 shows a schematic block diagram of a circuit arrangement 1 for transmitting uplink and downlink signals between at least one terminal 2 and at least one antenna 3 in a further embodiment. The circuit arrangement 1 shown in FIG. 3 is here configured substantially like the circuit arrangement 1 shown in FIG. 2. For this reason, reference is made to the corresponding descriptions regarding FIG. 2. In contrast to the embodiment shown in FIG. 2, the antenna 3 is here not part of the circuit arrangement 1. In contrast to FIG. 2, signal connections between the control and evaluating device 8 and the amplifier devices 6, 7 are shown by dotted lines, which serve for transmitting control signals.

It is further shown that the circuit arrangement comprises a further uplink filter device 14c which is also arranged in the first and second uplink paths SP1, . . . , SP2 and serves to provide the first and the second uplink signals. The further uplink filter device 14c is here part of the further multiplexer which, in the embodiment shown in FIG. 3, comprises the filter devices 14b and the further uplink filter device 14c. The further uplink filter device 14c can for example comprise bandpass filter devices.

The uplink amplifier devices 6 of the first and second uplink paths SP1, SP2 are here arranged in a frequency range-specific section of the first and second uplink paths SP1, . . . , SP2, which is arranged between the first multiplexer and the further multiplexer and serves to transmit uplink signals from precisely one uplink frequency range.

It is further shown that the circuit arrangement comprises a further downlink filter device 14d which is arranged in a combined downlink path EP4_5 and serves to provide the fourth and the fifth downlink signals. The further downlink filter device 14d is here part of the first multiplexer which, in the embodiment shown in FIG. 3, comprises the filter devices 14a and the further downlink filter device 14d.

Via the combined downlink path EP4_5, thus both the fourth and the fifth downlink signal can be transmitted. Here, the filter devices 14a can be configured such that they provide a signal which includes the frequency ranges of the fourth and the fifth download frequency range, but also further, in particular a frequency range lying between these frequency range. The further downlink filter device 14d can be arranged and/or configured such that signals from the fourth and fifth download frequency ranges are filtered out of this signal.

The further downlink filter device 14d is here arranged in a signal path section between the filter devices 14a of the first multiplexer and the filter devices 14b of the further multiplexer, particularly between the filter devices 14a of the first multiplexer and a downlink amplifier 7, which serves to amplify the fourth and fifth downlink signals. Thus, two different downlink signals can be conducted simultaneously via a common signal line, as a result of which a simultaneously activated state of two downlink signal paths is established.

It is furthermore shown that the circuit arrangement comprises a driver amplifier 6a which is arranged in a frequency range-specific section of the first and second uplink paths SP1, . . . , SP2, wherein this frequency range-specific section serves to transmit uplink signals from a plurality of, specifically two, uplink frequency ranges. The driver amplifier 6a is in this regard arranged in a signal path section between filter devices 14b and the further uplink filter devices 14c of the further multiplexer. However, the driver amplifier 6a is in this regard not necessarily part of the further multiplexer.

It is possible for the control and evaluating device 8 shown in FIG. 3 to be formed as a CPLD. Alternatively, also FPGAs, ASICs or further control units could be used. It is shown schematically that an operation of the uplink and downlink amplifier devices 6, 7 can be controlled by means of the control and evaluating device 8.

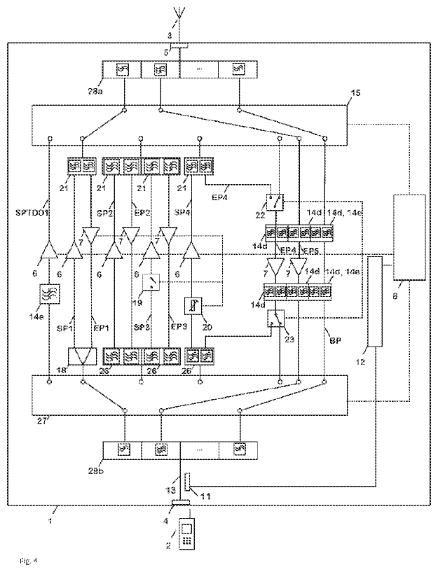

FIG. 4 shows a schematic block diagram of a circuit arrangement 1 for transmitting uplink and downlink signals between at least one terminal 2 and at least one antenna 3 in a further embodiment. The circuit arrangement 1 shown in FIG. 4 is here designed partially like the circuit arrangement 1 shown in FIG. 2. For this reason, reference is made to the corresponding descriptions regarding FIG. 2. In contrast to the embodiment shown in FIG. 2, the antenna 3 is here not part of the circuit arrangement 1.

Furthermore, it is shown that the first multiplexer comprises a first (antenna-sided) filter means 28a, a first (antenna-sided) switching device 15 as well as antenna-sided duplexers 21, downlink filter devices 14d and an uplink/downlink filter device 14e as well as a first switching element 22. In this regard, a signal connection on the antenna side of the first filter means 28a is connected to the interface 5 on the antenna side. Furthermore, signal connections on the terminal side of the first filter means 28a are connected to signal connections on the antenna side of the first switching arrangement 15. Furthermore, signal connections on the antenna side of the duplexer 21, of the downlink filter devices 14d, of the first switching element 22 and of the uplink/downlink filter device 14e are connected to signal connections of the terminal side of the first switching device 15. Frequency-specific sections of uplink signal paths SP1, . . . , SP4 and downlink paths EP1, . . . , EP4, EP5 as well as a bypass signal path BP, which serve to transmit signals from precisely one uplink or downlink frequency range or signals from a plurality of uplink or downlink frequency ranges, are connected to output connections on the terminal side of the duplexer 21, the downlink filter devices 14d, the first switching element 22 and the uplink/downlink filter device 14e.

It is furthermore shown that the further multiplexer comprises a further (terminal-sided) filter means 28b, a further (terminal-sided) switching device 27 as well as terminal-sided duplexers 26, further downlink filter devices 14d and a further uplink/downlink filter device 14e as well as a further switching element 23 and a power splitter 18.

In this regard, a signal connection on the terminal side of the further filter means 28b is connected to the interface 4 on the terminal side. Furthermore, signal connections on the antenna side of the further filter means 28b are connected to signal connections on the terminal side of the further switching device 27. Furthermore, signal connections on the terminal side of the duplexers 26, the power splitter 18, the further switching element 23 and the further downlink filter devices 14d as well as the further uplink/downlink filter device 14e are connected to signal connections on the antenna side of the further switching device 27. The frequency-specific sections of the uplink signal path SP1, . . . , SP4 and downlink paths EP1, . . . , EP4, EP5 and the bypass signal path BP are connected to the output connections on the antenna side of the duplexers 26, the power splitter 18, the further switching element 23, the further downlink filter devices 14d and the further uplink/downlink filter device 14e.

The first filter means 28a and the further filter means 28b can here comprise low pass filter devices, bandpass filter devices and/or high pass filter devices. The downlink and uplink/downlink filter devices 14d, 14e as well as the duplexers 21, 26 can in particular comprise bandpass filter devices which serve in particular for providing a signal with a frequency from at least precisely one uplink or downlink frequency range. These filter devices 14d, 14e can here in particular be designed corresponding to the downlink filter device 14d shown in FIG. 3.

By means of the switching devices 15, 27, one or several signal connections on the antenna side can be connected respectively to a signal connection on the terminal side of the switching device 15, 27. Switching states can in this regard be adjusted particularly by the control and evaluating device 8.

In this regard, frequency-specific uplink signal path sections SP1, . . . , SP2, SP3, SP4 connect a connection, on the antenna side, of the further switching device 27 to a connection, on the terminal side, of the first switching device 15, wherein respectively one uplink amplifier device 6 and duplexer 21 are arranged in the signal path sections. Furthermore, frequency-specific downlink signal path sections EP1, EP2, EP3, EP4 connect a connection on the terminal side of the first switching device 15 to a connection on the antenna side of the further switching device 27, wherein in each case one downlink amplifier device 7 and duplexer 21 are arranged in these signal path sections.

Furthermore, it is shown that the circuit arrangement 1, particularly the further multiplexer 10, comprises a power splitter 18 which is arranged both in a section of the first uplink signal path SP1 and in a section of the downlink signal path EP1. In the sections of the further uplink and downlink signal paths SP2, EP2, . . . , SP4, EP4 are arranged in each case duplexers 26.

It is further shown that the circuit arrangement comprises a TDD signal path section SPTDD1 for transmitting TDD signals. An uplink amplifier device 6 is arranged in this signal path section. Further, an uplink filter device 14e is arranged in this TDD signal path section. This TDD signal path section connects a connection on the antenna side of the further switching device 27 to a connection on the terminal side of the first switching device 15.

It is further shown that the circuit arrangement 1 comprises a disconnecting switching element 19, wherein this disconnecting switching element 19 is arranged in a frequency-specific section of the third uplink signal path SP3. A switching state of this disconnecting switching element 19 can be adjusted by the control and evaluating device 8. By changing the switching state, the third uplink signal path SP3 can be activated or deactivated.

It is further shown that the circuit arrangement 1 comprises a damping device 20, wherein this damping device 20 is arranged in a frequency-specific section of the fourth uplink signal path SP4. By means of adjusting the damping factor, an activated or a deactivated state of the fourth uplink signal path can be established.

Furthermore, it is shown that the circuit arrangement 1 comprises a first switching element 22. A first signal connection, on the antenna side, of the switching element 22 is connected to a signal connection, on the terminal side, of a duplexer 21 which is arranged in the fourth uplink signal path SP4 and fourth downlink signal path EP4. A second signal connection, on the antenna side, of the switching element 22 is connected to a signal connection, on the terminal side, of the first switching device 15. The single signal connection, on the terminal side, of the switching element 22 is connected to a connection, on the antenna side, of a downlink filter device 14d which is arranged in the fourth downlink signal path EP4. It is further shown that the circuit arrangement 1 comprises a further switching element 23. A first signal connection, on the terminal side, of the further switching element 23 is connected to a signal connection, on the antenna side, of a duplexer 26, which is arranged in the fourth uplink signal path SP4 and fourth downlink signal path EP4. A second signal connection, on the terminal side, of the further switching element 22 is connected to a signal connection, on the antenna side, of the further switching device 27. The single signal connection, on the antenna side, of the further switching element 23 is connected to a connection, on the terminal side, of a downlink filter device 14d which is arranged in the fourth downlink signal path EP4.

Thus, it is also possible for downlink signals, which are not filtered by the duplexers 21, 26, to be transmitted via a signal line, which can be a part of the fourth downlink signal path EP4. If the signal connection, on the antenna side, of the first switching element 22 is connected to the signal connection, on the terminal side, of the first switching device 15 and if the signal connection, on the antenna side, of the further switching element 23 is connected to the signal connection, on the antenna side, of the further switching device 27, thus it is facilitated that two different downlink signals from two different downlink frequency ranges are conducted simultaneously via a common signal line and in particular via a common downlink amplifier 7. In this case, thus a simultaneously activated state of two downlink paths is established.

Uplink and/or downlink signals can be transmitted via the bypass signal path BP without being amplified via an amplifier device. The bypass signal path BP can be activated or deactivated by means of the control of the switching devices 15 and/or 27.

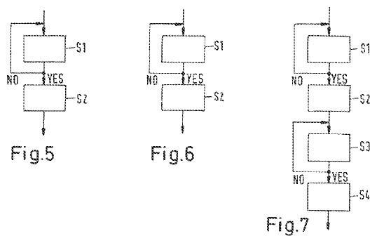

FIG. 5 shows a schematic flow diagram of a method according to the disclosure. In a first step S1 it is verified whether at least one uplink signal is present. If this is not the case, the method returns to the first step S1. If an uplink signal is detected and identified, thus in a second step S2 an activated state of the uplink path SP1, . . . , SP5 (see FIG. 1) assigned to the identified uplink signal and a simultaneously activated state of at least two downlink paths EP1, . . . , EP5 (see e.g. FIG. 1) is established.

FIG. 6 shows a schematic flow diagram of a method according to the disclosure in a further embodiment. In this regard, the first step S1 corresponds to the first step S1 shown in the embodiment according to FIG. 5. In a second step S2 of the method shown in FIG. 6, in contrast to the embodiment shown in FIG. 5, in addition also a simultaneously activated state of at least two uplink paths SP1, . . . , SP5 is established when the uplink signal is detected.

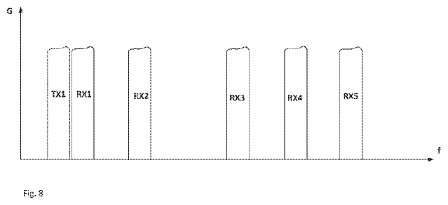

FIG. 7 shows a schematic flow diagram of a method according to the disclosure in a further embodiment. In this regard, the first two steps S1, S2 correspond to the steps S1, S2 shown in FIG. 5. In contrast to the embodiment shown in FIG. 5, in a third step S3 it is verified whether a further uplink signal is present. If this is not the case, the method returns to the third step S3. If, however, a further uplink signal is detected and identified, thus in a fourth step S4 an activated state of the further uplink path SP1, . . . , SP5 assigned to this identified further uplink signal is established.

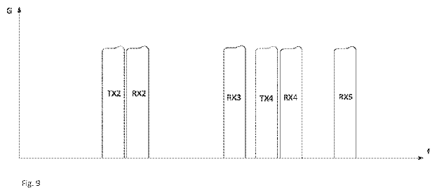

FIG. 8 shows a schematic representation of a transmission behaviour of a circuit arrangement 1 according to the disclosure the frequency range. Shown are a frequency f on the abscissa and the magnitude of the transmission function for the transmission direction TX from the terminal 2 to the antenna 3, or for the reception direction RX from the antenna 3 to the terminal 2 on the ordinate. Furthermore, five receiving bands RX1, RX2, RX3, RX4, RX5 are shown, wherein the downlink signals with frequencies from these receiving bands RX1, RX2, RX3, RX4, RX5 transmitted respectively via downlink signal paths EP1, . . . , EP5 which are different from one another and simultaneously activated (see e.g. FIG. 1).

In this example, furthermore, a transmitting band TX1 is shown, wherein the simultaneously activated state of the downlink signal paths EP1, . . . , EP5 is established or maintained when an uplink signal with a frequency from this transmitting band TX1 is detected. In the method according to the prior art, at the detection of this uplink signal, all downlink signal paths EP2, . . . , EP5 apart from the first downlink signal path EP1 was deactivated.

In this regard, the transmitting band TX1 and a first reception band RX1 can form a standard-specific FDD frequency range pair.

FIG. 9 shows a further schematic representation of a transmission behaviour of the circuit arrangement in the frequency range.

A frequency f is shown on the abscissa and the magnitude of the transmission function for the transmission direction TX from the terminal 2 to the antenna 3 or for the receiving direction RX from the antenna 3 to the terminal 2 is shown on the ordinate. Furthermore, four receiving bands RX2, RX3, RX4, RX5 are shown, wherein the downlink signals with frequencies from these receiving bands RX2, RX3, RX4, RX5 are transmitted in each case via downlink signal paths EP2, . . . , EP5 which are different from one another and simultaneously activated (see e.g. FIG. 1).

Furthermore, two transmitting bands TX2, TX4, specifically a second transmitting band TX2 and a fourth transmitting band TX4 are shown.

In this regard, it is shown that not all downlink signal paths EP1, . . . , EP5 are in an activated state. On the contrary, several, but not all downlink signal paths EP2, . . . , EP5 are activated, specifically a second, a third, a fourth and a fifth downlink signal path EP2, . . . , EP5, wherein the circuit arrangement also comprises a first downlink signal path EP1 which is, however, not in an activated state.

Furthermore, it is shown that not all uplink signal paths SP1, . . . , SP5 are in an activated state. On the contrary, several, but not all uplink signal paths SP2, SP4 are activated, specifically the second and the fourth uplink signal paths SP2, SP4, wherein, however, the circuit arrangement comprises also a first, a third and a fifth uplink signal path SP1, SP3, SP5, which are, however, not in an activated state.

The shown state is set when uplink signal with a frequency from the first transmitting band TX1 is detected or when uplink signal with a frequency from the second transmitting band TX2 is detected or when simultaneously an uplink signal with a frequency from the first transmitting band TX1 and an uplink signal with a frequency from the second transmitting band TX2 are detected. In the method according to the prior art, when one of these uplink signals is detected, all downlink signal paths EP1, . . . , EP5 apart from the downlink signal path EP2 or EP4 deactivated, via which the downlink signal corresponding to the detected uplink signal is transmitted, in order to form a FDD frequency range. In this regard, the second transmitting band TX2 and a second receiving band RX2 or a fourth transmitting band TX4 and a fourth receiving band RX4 could in each case form a standard-specific FDD frequency range pair. Furthermore, it was not possible according to the prior art to activate both transmitting bands TX2 and TX4.

It is possible for the shown state to be set when a terminal 2 transmits an uplink signal with a frequency from the second transmitting band TX2 and an uplink signal with a frequency from the fourth transmitting band TX4. Admittedly, the state can also be set when a terminal 2 transmits uplink signals an uplink signal with a frequency from the second transmitting band TX2 and a further terminal 2 transmits an uplink signal with a frequency from the fourth transmitting band TX4.

1. Circuit arrangement for transmitting uplink and downlink signals between at least one terminal and at least one antenna, wherein the circuit arrangement comprises:
at least one first uplink path for transmitting a first uplink signal and a first downlink path for transmitting a first downlink signal, wherein the circuit arrangement is configured to provide the uplink signals and the downlink signals and is further configured to detect at least one uplink signal, wherein the circuit arrangement is configure to establish an activated state of the uplink path to which the detected uplink signal is assigned; and
at least one further downlink path configured to transmit a further downlink signal, the circuit arrangement configured to establish a simultaneously activated state of at least two downlink paths, wherein the establishing or the maintaining of this activated state takes place when at least one uplink signal is detected and/or that the circuit arrangement comprises at least one further uplink path for transmitting a further uplink signal, wherein the circuit arrangement is further configured to establish a simultaneously activated state of at least two uplink paths, wherein the establishing or the maintaining of an activated state of at least two uplink paths takes place when an uplink signal or when at least two uplink signals is/are detected.

2. The circuit arrangement according to claim 1, wherein the activated uplink path and one of the activated downlink paths serve for FDD-based signal transmission.

3. The circuit arrangement according to claim 2, wherein the circuit arrangement is configured to establish or maintain, in operation, a simultaneously activated state of at least two downlink paths in response to takes place dependent on a previously known assignment between different uplink signals and downlink paths assigned to these different uplink signals.

4. The circuit arrangement according to claim 1, wherein the circuit arrangement is configured to assign to a first downlink frequency range set at least two of the downlink signals, wherein the circuit arrangement is configured to transmit, when establishing or the maintaining of the activated date of the downlink paths during operation, a downlink signal from one of the frequency ranges of the first downlink frequency range set and at least one downlink signal from a downlink frequency range which is not assigned to the first downlink frequency range set.

5. The circuit arrangement according to claim 4, wherein the circuit arrangement is configured so that, in operation, several, but not all, or all downlink signals which are not assigned to the first downlink frequency range set, can be transmitted.

6. The circuit arrangement according to claim 5, wherein the circuit arrangement is configured to use at least one power splitter to provide either the downlink signals or the uplink signals.

7. The circuit arrangement according to claim 6,
characterised in that an interface on the antenna side of the circuit arrangement is connected to a signal connection on the antenna side of the circuit arrangement for, wherein this signal connection on the antenna side is formed by a signal connection on the antenna side of circuit arrangement and the circuit arrangement is configured to filter the downlink signals.

8. The circuit arrangement according to claim 7, wherein the circuit arrangement is configured to establish an activated state that comprise at least one activatable amplifier device and/or at least one activatable damping device.

9. The circuit arrangement according to claim 8, wherein the circuit arrangement is configured to establish or maintain the activated state using state comprise at least one switching device.

10. The circuit arrangement according to claim 1, wherein the circuit arrangement is configured to detect several simultaneously transmitted uplink signals or a further uplink signal when an uplink signal has already been detected and/or an uplink path has been activated.

11. The circuit arrangement according to claim 10, wherein the circuit arrangement is configured to establish or maintain the activated state of the uplink paths required for transmitting all detected uplink signals, wherein the circuit arrangement is further configured to establish or maintain an activated state of downlink paths such that an FDD-based signal transmission is facilitated via all activated uplink and downlink paths.

12. The circuit arrangement according to claim 1, wherein the circuit arrangement comprises a signal path configured to transmit signals according to a time-duplex method.

13. The circuit arrangement according to claim 12, wherein the circuit arrange is configured to detect a time-duplex-based signal when an activated state of the uplink path and a deactivated state of the downlink path can be established to which the detected time-duplex-based signal is assigned.

14. Method for operating a circuit arrangement for transmitting uplink and downlink signals between at least one terminal and at least one antenna, comprising verifying whether at least one uplink signal is present, wherein a simultaneously activated state of at least two downlink paths is established or maintained when the uplink signal is detected and/or that a simultaneously activated state of at least two uplink paths is established or maintained when the uplink signal or when at least one further uplink signal is detected.

15. The method according to claim 14, wherein the establishing of the activated state is carried out by activating an amplifier device and/or by switching a switching device.
